(19) United States
(12) Patent Application Publication
(10) Pub. No.: US 2026/0118487 A1
(43) Pub. Date: Apr. 30, 2026

(54) EMITTER OF RANGING DEVICE AND RANGING DEVICE

(71) Applicant: STANLEY ELECTRIC CO., LTD., Tokyo (JP)

(72) Inventor: Masataka SUTO, Tokyo (JP)

(21) Appl. No.: 19/360,611

(22) Filed: Oct. 16, 2025

(30) Foreign Application Priority Data
Oct. 24, 2024 (JP) 2024-187235

(51) Int. Cl. G01S 7/484; G01R 19/00; G01S 7/481; G01S 7/4865; G01S 17/10

(52) U.S. Cl. CPC G01S 7/484; G01R 19/0084; G01S 7/4817; G01S 7/4865; G01S 17/10

(57) ABSTRACT

An emitter of a ranging device measuring a distance from an object, including: a transmitter outputting a transmission wave irradiating the object; a capacitor charged by a power supply and for supplying electrical current to the transmitter, a switching element controlling electrical current flowing to the transmitter; a drive circuit controlling the switching element; and a controller sending, after irradiation of the transmission wave, a control signal to the drive circuit in such a way as to consecutively irradiate with the transmission wave of a possible irradiation distance according to residual charge in the capacitor.

### CROSS-REFERENCE TO RELATED APPLICATIONS

This application claims the benefit of Japanese Patent Application No. 2024-187235, filed on Oct. 24, 2024, the entire disclosure of which is incorporated by reference herein.

### FIELD OF THE INVENTION

The present disclosure relates to an emitter of a ranging device and a ranging device.

### BACKGROUND OF THE INVENTION

To detect a position, a distance, a direction of existence, and the like of a preceding vehicle, an oncoming vehicle, a pedestrian, and the like, for example, a ranging device such as a light detection and ranging (LiDAR) device that detects a distance, a shape, and the like of an object by irradiating the object with laser light and measuring reflected light therefrom is used.

For example, Unexamined Japanese Patent Application Publication (Translation of PCT Application) No. 2022-516854 discloses an emitter array of a LiDAR device. The emitter array includes, in each of a plurality of channels, an emitter bank coupled between a high-side switch and a low-side switch. Further, the high-side switch is coupled between a capacitor and a power supply that supplies voltage to charge the capacitor, and controls charging of the capacitor. When charging is completed, the high-side switch is turned off and thereafter the low-side switch is turned on, thereby discharging the capacitor, so that the emitter bank can be driven.

### SUMMARY OF THE INVENTION

An emitter of a ranging device according to the present disclosure is an emitter of a ranging device measuring a distance from an object, including: a transmitter outputting a transmission wave irradiating the object; a capacitor charged by a power supply and for supplying electrical current to the transmitter; a switching element controlling electrical current flowing to the transmitter; a drive circuit controlling the switching element; and a controller sending, after irradiation of the transmission wave, a control signal to the drive circuit in such a way as to consecutively irradiate with the transmission wave of a possible irradiation distance according to residual charge in the capacitor.

### BRIEF DESCRIPTION OF DRAWINGS

A more complete understanding of this application can be obtained when the following detailed description is considered in conjunction with the following drawings, in which:

FIG. 1 is a block diagram illustrating a configuration of a ranging device according to an embodiment of the present disclosure;

FIG. 2 is a block diagram illustrating a configuration of an emitter of the ranging device according to the embodiment of the present disclosure;

FIG. 3 is a diagram illustrating voltage fluctuation of a capacitor during laser irradiation;

FIG. 4 is a diagram illustrating voltage fluctuation of the capacitor during laser irradiation when capacitance of the capacitor is varied;

FIG. 5A is a view illustrating an example of ranging using the ranging device according to the embodiment of the present disclosure, and is a front elevational view as seen forward from a vehicle;

FIG. 5B is a view illustrating an example of ranging using the ranging device according to the embodiment of the present disclosure, and is a top view as seen above the vehicle;

FIG. 6A is a diagram illustrating an example of a combination of irradiation distances, and is a diagram illustrating a combination of irradiation distances when two consecutive irradiations are performed; and

FIG. 6B is a diagram illustrating an example of a combination of irradiation distances, and is a diagram illustrating a combination of irradiation distances when three consecutive irradiations are performed.

### DETAILED DESCRIPTION OF THE INVENTION

Hereinafter, a ranging device according to an embodiment of the present disclosure is described with reference to drawings. In the drawings, the same or equivalent parts are denoted by the same reference signs.

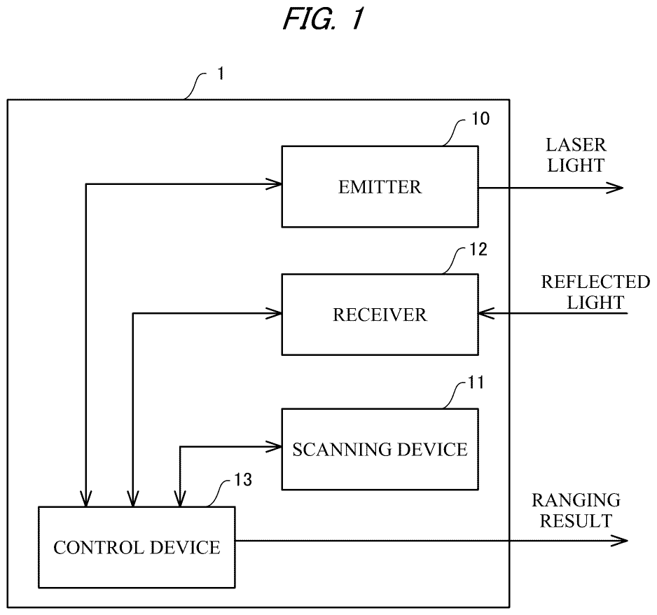

FIG. 1 is a block diagram illustrating a configuration of a ranging device 1. In the present embodiment, the ranging device 1 is a LiDAR device that is an optical ranging device. The ranging device 1 is mounted on, for example, a front portion of a vehicle, and detects a preceding vehicle, an oncoming vehicle, a pedestrian, an obstacle, and the like. The ranging device 1 includes an emitter 10 that is a laser irradiating device irradiating an object with laser light, a scanning device 11 that scans irradiating laser light within a measurement range, a receiver 12 that is a light receiving device receiving light reflected from the object, and a control device 13 that controls operation of the emitter 10, the scanning device 11, and the receiver 12 and calculates a distance from the object.

The emitter 10 includes light sources that are transmitters of the number of channels according to, for example, vertical resolution, the light sources for the channels being arranged in a vertical direction. The light source is a laser diode and emits, as a transmission wave, for example, near-infrared pulsed laser light having a wavelength of approximately 900 nm. Timing for light emission and light off of the light source is controlled individually for each channel. The emitter is described later in detail.

The scanning device 11 scans laser light emitted from the emitter 10 within a measurement range by using an optical deflector. The optical deflector includes, for example, a micro electro mechanical system (MEMS) mirror. The optical deflector reflects incident light incident from a fixed direction with a mirror rotating about mutually orthogonal axes, and emits the reflected light as scanning light.

The receiver 12 receives reflected light of laser light emitted from the emitter 10 and reflected by an object. The receiver 12 includes a plurality of light receiving elements arranged in a two-dimensional direction. The light receiving element includes, for example, a single photon avalanche diode (SPAD), a complementary metal oxide semiconductor (CMOS), a charge coupled device (CCD), and the like. The receiver 12 outputs, to the control device 13, a detection signal according to intensity of received light.

The control device 13 controls operation of the emitter 10, the scanning device 11, and the receiver 12. The control device 13 selects a channel of a light source emitting light within the emitter 10, and controls driving of the mirror of the optical deflector of the scanning device 11. Further, the control device 13 calculates a distance to an object by using a detection signal input from the receiver 12. The control device 13 calculates time of flight (TOF) from emission of laser light to reception of reflected light, calculates a distance to an object from the calculated time of flight and velocity of laser light, and outputs a ranging result. The control device 13 includes, for example, a microcomputer.

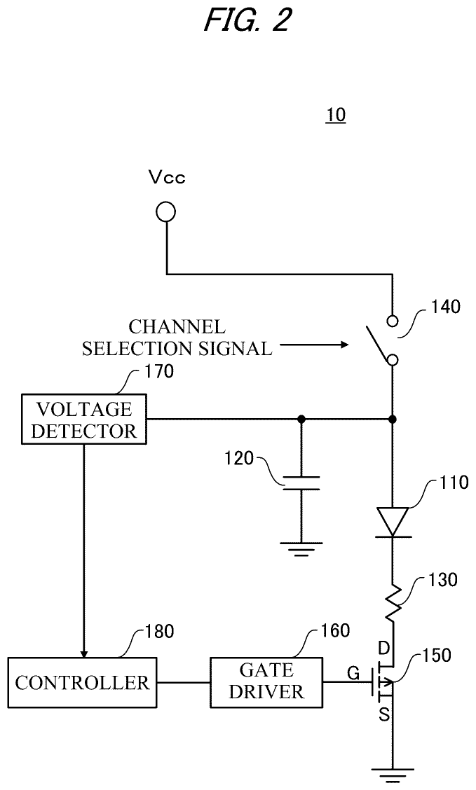

Next, FIG. 2 is a block diagram illustrating a configuration of the emitter 10 of the ranging device 1 in FIG. 1. Here, while a configuration for one channel is illustrated in FIG. 2, similar configurations are provided for the number of channels in reality. The emitter 10 includes a laser diode 110, a capacitor 120, a resistor 130, a channel selection switch 140 for connecting a power supply Vcc to the capacitor 120 upon receiving a channel selection signal for selecting a channel, a switching element 150 that turns on/off light emission of the laser diode 110, a gate driver 160 that is a drive circuit controlling on/off of the switching element 150, a voltage detector 170 that detects voltage of the capacitor 120, and a controller 180 that supplies a signal for light emission timing of the laser diode 110 to the gate driver 160.

The capacitor 120 is connected to the power supply Vcc and the laser diode 110 at one end via the channel selection switch 140. Further, another end of the capacitor 120 is connected to ground. The power supply Vcc supplies direct current voltage, and charges the capacitor 120 when the channel selection switch 140 is on. The resistor 130 is connected to set a current value flowing through the laser diode 110. The charged capacitor 120 supplies electrical current to the laser diode 110, causing the laser diode 110 to emit light. Light intensity can be changed by changing capacitance of the capacitor 120 and a resistance value of the resistor 130.

The channel selection switch 140 is a switch that connects the capacitor 120 to the power supply Vcc for charging, and is also a switch that selects the laser diode 110 in a channel for emitting light. As described above, the capacitor 120 and the channel selection switch 140 are provided for each channel, and, by sequentially selecting each channel, the laser diode 110 in the selected channel is sequentially caused to emit light. A channel selection signal for causing the laser diode 110 to emit light is supplied from the control device 13. The switch is switched from off to on upon receiving a selection signal for selecting the own channel. When the channel selection switch 140 is turned on, the power supply Vcc is connected to the capacitor 120 and the capacitor 120 is charged. The channel selection switch 140 is kept on for a fixed period of time to complete charging of the capacitor 120, and is thereafter switched to off. Note that, as for transition from on to off, the channel selection switch 140 may be kept on only during receiving a selection signal, and may thereafter transition to off.

The switching element 150 is a field-effect transistor (FET). A drain D of the switching element 150 is connected to the laser diode 110 via the resistor 130, and a source S is connected to ground. The switching element 150 is turned on/off according to gate voltage. By turning on the switching element 150, electrical charge charged in the capacitor 120 flows to the laser diode 110, causing the laser diode 110 to emit light.

The gate driver 160 is a drive circuit that is connected to a gate G of the switching element 150 and applies voltage for controlling on/off of the switching element 150. The gate driver 160 drives switching of the switching element 150 based on an input signal from the controller 180.

The controller 180 is connected to the control device 13, the voltage detector 170, and the gate driver 160, and outputs a control signal to the gate driver 160 based on an input signal from the control device 13 and the voltage detector 170. To the controller 180, a laser light emission timing signal that is a timing signal for causing the laser diode 110 to emit light is supplied from the control device 13. Further, to the controller 180, a detection signal for charge voltage of the capacitor 120 detected at the voltage detector 170 is supplied. The controller 180 supplies, to the gate driver 160, a pulsed trigger signal for causing the laser diode 110 to emit pulsed light based on the detection signal, with the laser light emission timing signal as timing for starting light emission.

The voltage detector 170 is connected in parallel with the capacitor 120, and detects charge voltage of the capacitor 120. Detection of voltage is performed by, for example, connecting a detection resistor to one end of the capacitor 120. A detection signal is supplied to the controller 180. This allows the controller 180 to detect how much electrical charge remains in the capacitor 120.

The emitter 10 turns on the switch upon receiving a channel selection signal from the control device 13 to charge the capacitor 120, thereafter supplies, by the controller 180, a trigger signal to the gate driver 160 upon receiving a light emission timing signal from the control device 13, and keeps, by the gate driver 160, the switching element 150 on for predetermined pulse time, thereby causing the laser diode 110 to emit light. Here, the capacitor 120 needs to have enough capacitance to supply enough energy to satisfy a desired light intensity according to an irradiation distance of laser light. Further, a relationship between a discharge characteristic of the capacitor 120 and irradiation time of the emitter 10 also needs to be considered. The irradiation distance is a distance over which laser light that is a transmission wave reaches with light intensity capable of detecting an object, and is also called a detection distance.

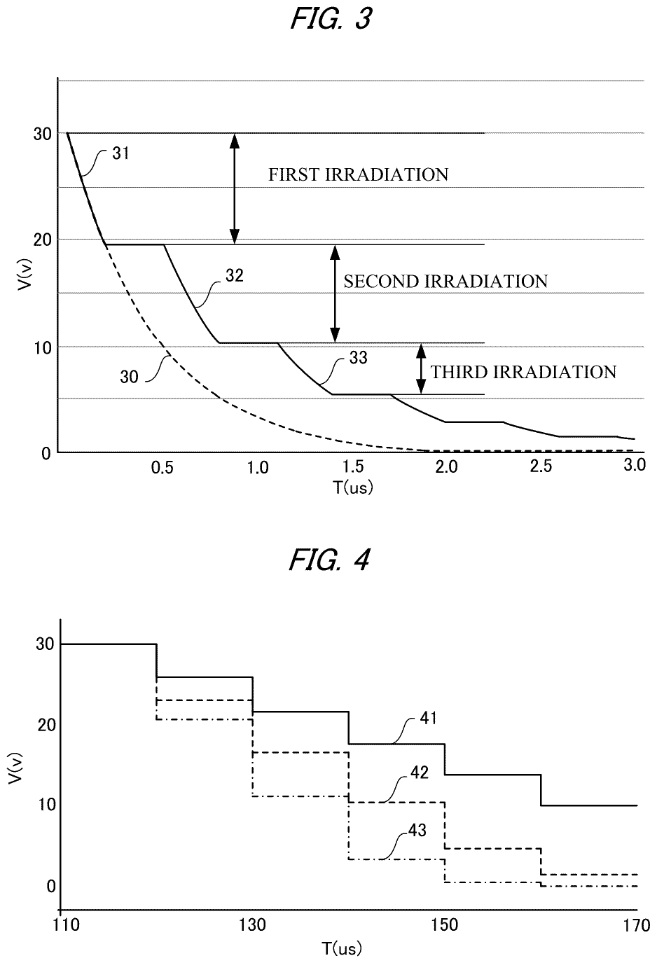

FIG. 3 illustrates voltage fluctuation of the capacitor 120 during laser irradiation, with a vertical axis representing voltage and a horizontal axis representing time. A discharge curve 30 illustrated by a dotted line indicates a discharge characteristic of the capacitor 120. First, a first irradiation is performed for a predetermined pulse period when the capacitor is completely charged. Thereby, electrical charge charged in the capacitor 120 is discharged. However, when utilizing an area with high response speed of the capacitor 120, the electrical charge in the capacitor 120 cannot be fully discharged in a single irradiation. As indicated in a discharge curve 31 that is a part of the discharge curve 30, the voltage drops after the first irradiation but only from 30 V to 19.5 V and the electrical charge is not fully discharged. At the completion of the first irradiation, the controller 180 detects the voltage of the capacitor 120 from the voltage detector 170. This allows the controller 180 to detect how much electrical charge remains in the capacitor 120. The controller 180 determines whether a subsequent irradiation is possible based on the detected voltage value and the discharge characteristic, and, when an irradiation is possible, determines a possible irradiation distance. When an irradiation distance is determined, a second irradiation is performed for a predetermined pulse period. When a second irradiation is started, the residual charge is discharged according to the discharge curve 30, and the voltage drops as indicated in a discharge curve 32 that is a part of the discharge curve 30.

At the completion of the second irradiation, the controller 180 detects the voltage of the capacitor 120 from the voltage detector 170 again. The controller 180 determines whether a subsequent irradiation is possible based on the detected voltage value and the discharge characteristic, and, when an irradiation is possible, determines a possible irradiation distance. When an irradiation distance is determined, a third irradiation is performed for a predetermined pulse period. When a third irradiation is started, the residual charge is discharged according to the discharge curve 30, and the voltage drops as indicated in a discharge curve 33 that is a part of the discharge curve 30.

Hereinafter, in a same way, at each completion of irradiation, the controller 180 repeats detecting the voltage of the capacitor 120 from the voltage detector 170, determining whether a subsequent irradiation is possible based on the detected voltage value and the discharge characteristic, when an irradiation is possible, determining a possible irradiation distance, and performing an irradiation for a predetermined pulse period. When it is determined that no irradiation is possible, the above processing is ended.

FIG. 4 illustrates an example of voltage fluctuation of the capacitor 120 when capacitance of the capacitor 120 is varied. Herein, an example of using the capacitor 120 having three different capacitances, large, medium, and small, with five consecutive irradiations is illustrated. A discharge curve 41 indicates voltage fluctuation when the capacitor 120 has a large capacitance, a discharge curve 42 indicates voltage fluctuation when the capacitor 120 has a medium capacitance, and a discharge curve 43 indicates voltage fluctuation when the capacitor 120 has a small capacitance. From this, even though the initial voltage is the same, voltage drop due to discharge required for a single irradiation is also larger in the discharge curve 43 than in the discharge curve 42. That is, the larger the capacitance of the capacitor 120, the greater the electrical charge stored, and thus voltage drop due to discharge required for a single irradiation is small. Accordingly, the larger the capacitance of the capacitor 120, the longer the irradiation distance of second and subsequent irradiations can be, and the capacitance of the capacitor 120 is set according to the irradiation distance of second and subsequent irradiations.

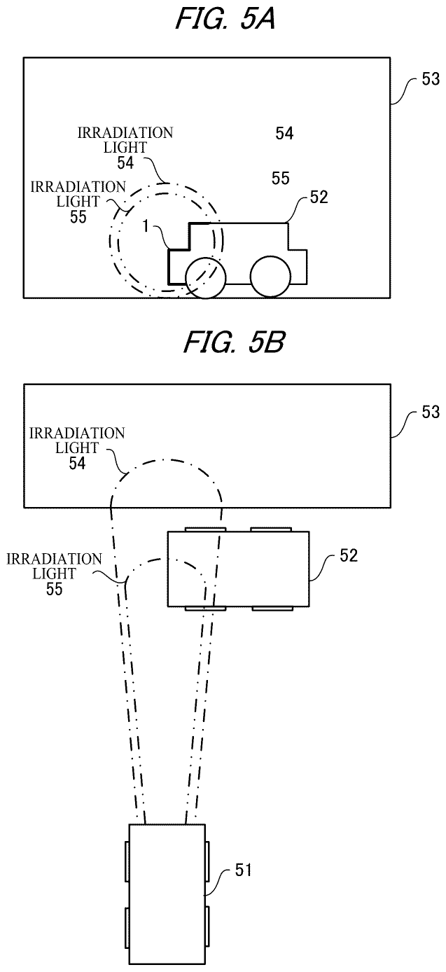

Next, FIGS. 5A and 5B illustrate an example of ranging using the ranging device 1 according to the present embodiment. FIGS. 5A and 5B illustrate ranging when the ranging device 1 is mounted on a vehicle 51, the ranging device 1 irradiating with laser light from a front end of the vehicle 51 in order to measure a forward distance of the vehicle 51. FIG. 5A illustrates a front elevational view as seen forward from the vehicle 51, and FIG. 5B illustrates a top view as seen above the vehicle 51. In front of the vehicle 51, there are a vehicle 52 crossing forward and a wall 53 located behind the vehicle 52. The ranging device 1 consecutively irradiates with two types of laser light having different irradiation distances, irradiation light 54 that is pulsed light having a longer irradiation distance and irradiation light 55 that is pulsed light having a shorter irradiation distance than this. Here, the irradiation light 54 has an irradiation distance (detection distance) capable of detecting a distance to the wall 53 arranged behind the vehicle 52. In contrast, the irradiation light 55 has an irradiation distance (detection distance) capable of detecting a distance to the vehicle 52 but incapable of detecting a distance to the wall 53. In this way, consecutive irradiations of laser pulsed light having different irradiation distances have an advantageous effect of improving detection accuracy in detecting objects overlapping in a depth direction. With the irradiation light 54 having a longer irradiation distance, a contour of the vehicle 52 that is a boundary between the vehicle 52 and the wall 53 is detected ambiguously, since the vehicle 52 that is a foreground object and the wall 53 that is a background object overlap. Here, irradiating with the irradiation light 55 having a short irradiation distance enables detection of only the vehicle 52 that is a foreground object, which can improve detection accuracy for an object at a short distance.

In the above embodiment, the voltage detector 170 is provided to detect voltage of the capacitor 120, determine an irradiation distance, and control irradiation timing of consecutively irradiating laser pulsed light. In contrast, without providing the voltage detector 170 and without using a result of detection by the voltage detector, capacitance of the capacitor 120, a resistance value of the resistor 130, and a numerical value preliminarily modeled with a plurality of irradiation timings as parameters are used to determine a plurality of irradiation distances and control consecutive irradiations by the plurality of irradiation distances. The numerical value is set by measurement during manufacture, adjustment, or the like of the ranging device 1 or the emitter 10. Alternatively, past settings of capacitance of the capacitor 120, a resistance value of the resistor 130, and a plurality of irradiation timings for a plurality of irradiation distances and the number of irradiations may be stored, and the numerical value may be set based on these settings. Note that, the number of irradiations may be further increased to three or four in conjunction with tuning capacitance of the capacitor 120.

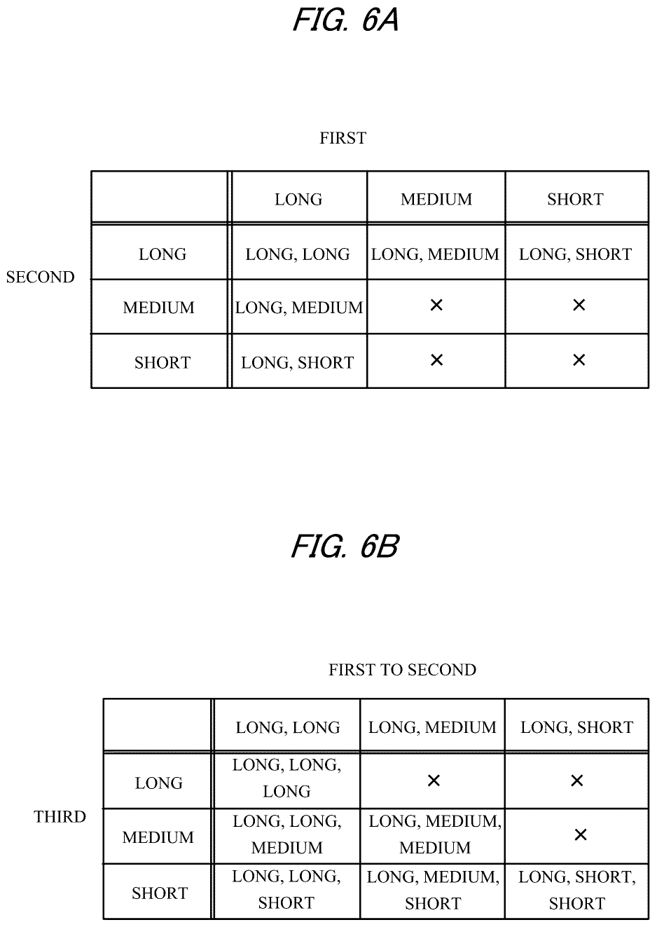

In consecutive irradiations of laser pulsed light of a plurality of irradiation distances, detection accuracy can be improved by setting a combination of irradiation distances according to a purpose of detection. Here, as examples, FIG. 6A illustrates a combination of irradiation distances when two consecutive irradiations are performed, and FIG. 6B illustrates a combination of irradiation distances when three consecutive irradiations are performed.

In the example of two consecutive irradiations, a second irradiation distance when a first irradiation distance is a long distance is any of long, medium, and short distances. Accordingly, there are three types of combinations of the first irradiation and the second irradiation, long distance+long distance, long distance+medium distance, and long distance+short distance, as illustrated in FIG. 6A.

Further, in the example of three consecutive irradiations, a third irradiation distance for each of the above three types of combinations when two consecutive irradiations are performed is any of long, medium, and short distances. However, when the second irradiation distance is a medium distance, the third irradiation distance is either a medium or short distance, because any distance longer than this cannot be irradiated due to amount of residual charge in the capacitor 120. Further, when the second irradiation distance is a short distance, the third irradiation distance is only a short distance, because any distance longer than this cannot be irradiated due to amount of residual charge in the capacitor 120. Accordingly, there are six types of combinations of three consecutive irradiations, long distance+long distance+long distance, long distance+long distance+medium distance, long distance+long distance+short distance, long distance+medium distance+medium distance, long distance+medium distance+short distance, and long distance+short distance+short distance, as illustrated in FIG. 6B. Setting for control of continuous irradiations by a plurality of irradiation distances may be performed by making selection from among these combinations according to a distance desired to improve detection accuracy.

As described above, an irradiation distance of subsequently irradiating laser light can be calculated from the voltage and the discharge characteristic of the capacitor 120, and consecutive irradiations of laser pulsed light having different irradiation distances can be performed in a single charging operation. Then, by setting laser pulsed light having different irradiation distances, a boundary between objects to be detected caused by overlapping of the objects at mutually different distances and a contour of an object are detected with improved accuracy, which improves safety. Further, since second and subsequent irradiations use residual charge in the capacitor 120, there arises no loss of residual charge that is simply discharged and discarded. Furthermore, a switch for discharging and discarding residual charge is no longer necessary, which has an advantageous effect of reducing cost, simplification, and miniaturization.

Note that, in the above embodiment, an FET is used as an example of the switching element 150, but, without limitation thereto, a bipolar transistor or an insulated gate transistor may be used.

Further, in the above embodiment, a voltage detection signal is input to the controller 180 and a control signal for causing the laser diode 110 to emit pulsed light is generated by the controller 180, but, without limitation thereto, for example, a voltage detection signal may be input to the control device 13 and a control signal for causing the laser diode 110 to emit pulsed light is generated by the control device 13.

Further, in the above embodiment, the configuration is made such that the laser diode 110 is provided for the number of a plurality of channels and, by sequentially selecting each channel, the laser diode 110 in the selected channel is sequentially caused to emit light. In contrast, the configuration may be adapted to a flash-type device that does not scan light but irradiates a wide area with light.

Further, in the above embodiment, a LiDAR is used as an example of the ranging device, but, without limitation thereto, for example, an ultrasonic sensor that measures a distance by ultrasonic waves may be used.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. An emitter of a ranging device measuring a distance from an object, comprising:
a transmitter outputting a transmission wave irradiating the object;
a capacitor charged by a power supply and for supplying electrical current to the transmitter;
a switching element controlling electrical current flowing to the transmitter;
a drive circuit controlling the switching element; and
a controller sending, after irradiation of the transmission wave, a control signal to the drive circuit in such a way as to consecutively irradiate with the transmission wave of a possible irradiation distance according to residual charge in the capacitor.

2. The emitter of a ranging device according to claim 1, further comprising a voltage detector detecting voltage of the capacitor,
wherein the controller determines the irradiation distance according to residual charge in the capacitor based on voltage detected by the voltage detector, and sends the control signal to the drive circuit in such a way as to irradiate with the transmission wave of the irradiation distance.

3. The emitter of a ranging device according to claim 1, wherein the controller determines the irradiation distance by using capacitance of the capacitor, a resistance value setting a current value flowing through the transmitter, and a numerical value modeled with a plurality of irradiation timings as parameters, and sends the control signal to the drive circuit in such a way as to irradiate with the transmission wave of the irradiation distance.

4. The emitter of a ranging device according to claim 1, wherein the ranging device is a LiDAR device.

5. The emitter of a ranging device according to claim 1, wherein the ranging device is an ultrasonic sensor.

6. A ranging device comprising:
the emitter according to claim 1;
a scanning device scanning the irradiating transmission wave within a measurement range;
a receiver receiving the transmission wave reflected from the object; and
a control device controlling operation of the emitter, the scanning device, and the receiver and calculating a distance from the object.
